(19) United States
(12) Patent Application Publication
(10) Pub. No.: US 2016/0225721 A1
(43) Pub. Date: Aug. 4, 2016

(54) SEMICONDUCTOR PACKAGE

(71) Applicant: SAMSUNG ELECTRONICS CO., LTD., SUWON-SI (KR)

(72) Inventors: EUN-KYOUNG CHOI, HWASEONG-SI (KR); SANG-UK HAN, HWASEONG-SI (KR); CHA-JEA JO, INCHEON (KR); TAE-JE CHO, YONGIN-SI (KR)

(21) Appl. No.: 14/957,741

(22) Filed: Dec. 3, 2015

(30) Foreign Application Priority Data
Feb. 2, 2015 (KR) 10-2015-0016188

(51) Int. Cl. H01L 23/544; H01L 25/065; H01L 23/00; H01L 23/31

(52) U.S. Cl. CPC H01L 23/544; H01L 23/31; H01L 25/0655; H01L 24/49; H01L 2223/54413; H01L 2223/54406; H01L 2223/5444

(57) ABSTRACT

A semiconductor package having an upper surface, a lower surface, and at least one side surface is provided. The semiconductor package includes a mold member disposed on the upper surface and at least one side surface of a semiconductor chip included in the semiconductor package. A marking pattern in the semiconductor package having information about the semiconductor chip is formed on at least one side surface of the mold member.

### CROSS-REFERENCE TO RELATED APPLICATION

The present application claims priority to and the benefit of Korean Patent Application No. 10-2015-0016188, filed on Feb. 2, 2015, in the Korean Intellectual Property Office, the entire contents of which is incorporated by reference herein.

### BACKGROUND

The inventive concept relates to a semiconductor package, and more particularly, to a semiconductor package having a marking pattern formed on at least one side thereof in order to prevent a semiconductor device being deemed inferior as a result from forming marking patterns directly on semiconductor chips included in the semiconductor package.

In the electronic product market, the demand for portable devices has rapidly increased, and there is an ongoing demand to reduce the size and weight of electronic components to be mounted therein. The entire thickness of the semiconductor package is continuously being decreased to reduce the size and weight of the electronic components, and there is ongoing demand to increase memory capacity. A thin semiconductor chip stack can help realize a large capacity memory in a semiconductor package, and thus the entire thickness of the semiconductor package, in addition to the thicknesses of a semiconductor chip and a mold member covering the semiconductor chip, is continuously being decreased.

### SUMMARY

The inventive concept provides a semiconductor package having a marking pattern on at least one side of the semiconductor package.

The inventive concept may be embodied in many different forms and should not be construed as being limited to the exemplary embodiments set forth herein. Rather, the exemplary embodiments are provided so that this disclosure will be thorough and complete, and will fully convey the concept of the inventive concept to those skilled in the art.

According to an aspect of the inventive concept, there is provided a semiconductor package having an upper surface, a lower surface, and at least one side surface.

A marking pattern having information about a semiconductor chip is formed on at least one side surface of the semiconductor package.

An average roughness of the side of the semiconductor package may be 0.4 μm to 0.8 μm.

A portion of the upper surface of the semiconductor chip may be exposed.

A mold member may be disposed on an upper surface and at least one side surface of a semiconductor chip included in the semiconductor package, and a thickness of the mold member on the upper surface of the semiconductor chip may be less than a thickness of the mold member on the at least one side of the semiconductor chip.

The marking pattern may be recessed and may be readable by a recognition device.

An angle between the upper surface and the at least one side of the semiconductor package may be a right angle.

The marking pattern may include a character and an identification symbol indicating information about the semiconductor package.

The marking pattern may include a bar code shape in which the information about the semiconductor package is stored.

The marking pattern may be formed on the at least one side surface of the semiconductor package by using a laser irradiation method.

The marking pattern may be formed on the at least one side surface of the semiconductor package by using an inkjet printing method.

According to an aspect of the inventive concept, there is provided a semiconductor package having a mold member, and a semiconductor chip having a first surface, a second surface facing the first surface and bonding pads disposed on the first surface A marking pattern having information about the semiconductor chip is formed on an external surface of the semiconductor package parallel to a third surface contacting the first and second surfaces, respectively.

The mold member may cover the third surface, and the marking pattern is formed on the external surface of the mold member parallel to the third surface.

A thickness of the mold member in a direction perpendicular to the first surface may be less than a thickness of the mold member in a direction perpendicular to the third surface.

The marking pattern may include at least one from among a character, a number, an identification symbol, and a bar code.

The marking pattern may be directly formed on the external surface of the semiconductor package parallel to the third surface.

The semiconductor package may include a plurality of semiconductor chips.

### BRIEF DESCRIPTION OF THE DRAWINGS

FIG. 1 is a sectional view of a semiconductor package having a marking pattern formed on at least one side thereof by using a laser irradiation method, according to an exemplary embodiment.

FIG. 2 is a sectional view of a semiconductor package having a marking pattern formed on at least one side thereof is by using an inkjet printing method, according to an exemplary embodiment.

FIG. 3 is a sectional view of a semiconductor package of a flip chip structure having a marking pattern on at least one side of the semiconductor package, according to an exemplary embodiment.

FIG. 4 is a sectional view of a semiconductor package having a bonding wire structure and having a marking pattern on at least one side of the semiconductor package, according to an exemplary embodiment.

FIG. 5 is a sectional view of a semiconductor package of a semiconductor chip stack structure having a marking pattern on at least one side of the semiconductor package, according to an exemplary embodiment.

FIG. 6 is a sectional view of a semiconductor package of a through silicon via (TSV) structure having a marking pattern on at least one side of the semiconductor package, according to an exemplary embodiment.

FIG. 7 is a side view of a semiconductor package having a marking pattern on at least one side thereof, according to an exemplary embodiment.

FIG. 8 is a perspective view of a semiconductor package having a marking pattern on at least one side thereof, according to an exemplary embodiment.

FIG. 9 is a graph illustrating surface roughnesses of an upper surface and a side of a semiconductor package, according to an exemplary embodiment.

FIG. 10 is a plan view of a memory module having a semiconductor package, according to an exemplary embodiment.

FIG. 11 is a configuration diagram of a system having a semiconductor package, according to an exemplary embodiment.

FIG. 12 is a configuration diagram of a memory card having a semiconductor package, according to an exemplary embodiment.

### DETAILED DESCRIPTION OF THE EMBODIMENTS

The inventive concept may, however, be embodied in many different forms and should not be construed as being limited to the embodiments set forth herein. Rather, these embodiments are provided so that this disclosure will be thorough and complete, and will fully convey the inventive concept to those of ordinary skill in the art. It should be understood, however, that there is no intent to limit the inventive concept to the particular forms disclosed, but on the contrary, the inventive concept is to cover all modifications, equivalents, and alternatives falling within the spirit and scope of the inventive concept. Like reference numerals denote like elements throughout the specification and drawings. In the drawings, the dimensions of structures are exaggerated for clarity of the inventive concept. As used herein, the term “and/or” includes any and all combinations of one or more of the associated listed items.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

Also, though terms “first” and “second” are used to describe various members, components, regions, layers, and/or portions in various embodiments of the inventive concept, the members, components, regions, layers, and/or portions are not limited to these terms. These terms are used only to differentiate one member, component, region, layer, or portion from another one. Therefore, a member, a component, a region, a layer, or a portion referred to as a first member, a first component, a first region, a first layer, or a first portion in an embodiment may be referred to as a second member, a second component, a second region, a second layer, or a second portion in another embodiment.

The terminology used herein is for the purpose of describing particular embodiments only and is not intended to be limiting of the inventive concept. As used herein, the singular forms “a,” “an,” and “the” are intended to include the plural forms as well, unless the context clearly indicates otherwise. It will be understood that terms such as “comprise,” “include,” and “have,” when used herein, specify the presence of stated features, integers, steps, operations, elements, components, or combinations thereof, but do not preclude the presence or addition of one or more other features, integers, steps, operations, elements, components, or combinations thereof.

Unless otherwise defined, all terms used herein, including technical and scientific terms, have the same meaning as commonly understood by one of ordinary skill in the art to which the inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Unless otherwise defined, a vertical direction or a horizontal direction refers to a vertical direction or a horizontal direction with respect to a principal surface of a package substrate. In addition, unless otherwise defined, a top surface of a component stacked on the package substrate is a surface opposite to the package substrate, and a bottom surface thereof is a surface facing the package substrate.

Hereinafter, exemplary embodiments of the inventive concept will be described in more detail with reference to the accompanying drawings.

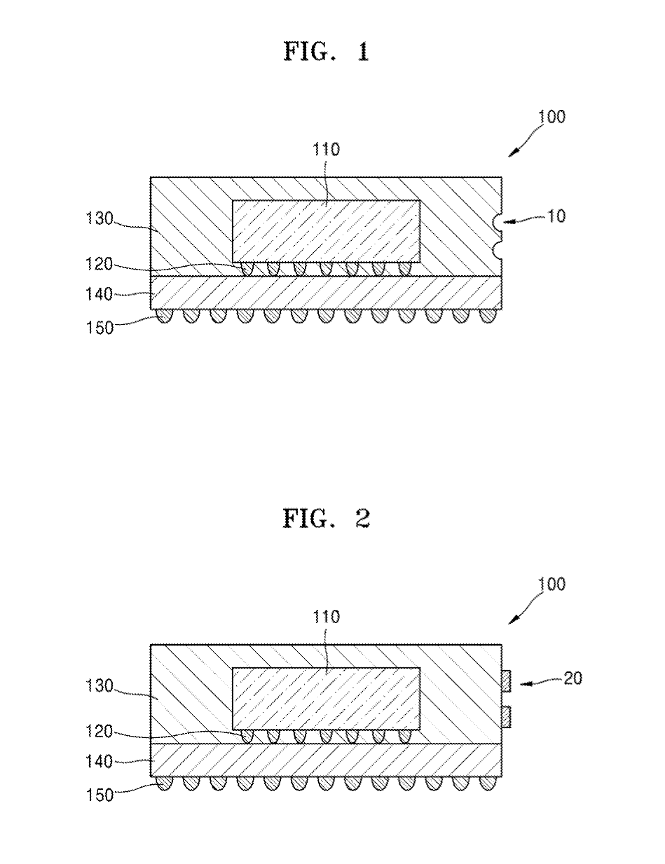

FIG. 1 is a sectional view of a semiconductor package having a marking pattern formed on at least one side thereof by using a laser irradiation method, according to an exemplary embodiment.

Referring to FIG. 1, in a flip-chip type semiconductor package 100, a semiconductor chip 110 is directly connected to a package substrate 140 via an internal connection member 120, and the package substrate 140 includes an external connection member 150.

The semiconductor chip 110 may include a body part, a wiring part, and a protection part. The semiconductor chip 110 may be formed based upon a wafer.

When the semiconductor chip 110 is formed based upon a wafer, the body part may include a semiconductor substrate, an integrated circuit layer, and an interlayer insulating film. In addition, the wiring part, which is disposed on the body part, may include an inter-metal insulating layer and multilayer wiring formed within the inter-metal insulating layer.

Examples of the semiconductor substrate, which is the base of the body part, may include a group IV material wafer, such as a silicon wafer, or a group III-V compound wafer. In addition, the semiconductor substrate may be formed from a single crystalline wafer, such as a single crystalline silicon wafer, according to a manufacturing method. However, the semiconductor substrate is not limited to a single crystalline wafer. An epitaxial wafer, a polished wafer, an annealed wafer, a silicon-on-insulator (SOI) wafer, or the like may be used as the semiconductor substrate. The epitaxial wafer means a wafer in which a crystalline material is grown on a single crystalline silicon substrate.

The protection part may be formed on the wiring part in a direction of the active surface. The protection part may protect the semiconductor chip 110 from external physical and chemical damage.

The semiconductor chip 110 may include a memory device or a non-memory device. Examples of the memory device may include a dynamic random access memory (DRAM), a static random access memory (SRAM), a flash memory, an electrically erasable and programmable read only memory (EEPROM), a phase-change random access memory (PRAM), a magnetoresistive random access memory (MRAM), and a resistive random access memory (RRAM). Examples of the non-memory device may include logic devices, such as a microprocessor, a digital signal processor, and a microcontroller, or other similar devices.

The internal connection member 120 may be a solder ball. A plurality of pads (not shown) may be disposed on the active surface of the semiconductor chip 110, and the internal connection member 120 may be electrically connected to the pads. The internal connection member 120 may include only a copper pillar, or may include a copper pillar and a solder ball.

FIG. 1 illustrates that only the internal connection member 120 is formed on the semiconductor chip 110, but this is only for simplicity of illustration of the cross-section and convenience of understanding. In practice, various types of pads may be disposed on the active surface of the semiconductor chip 110.

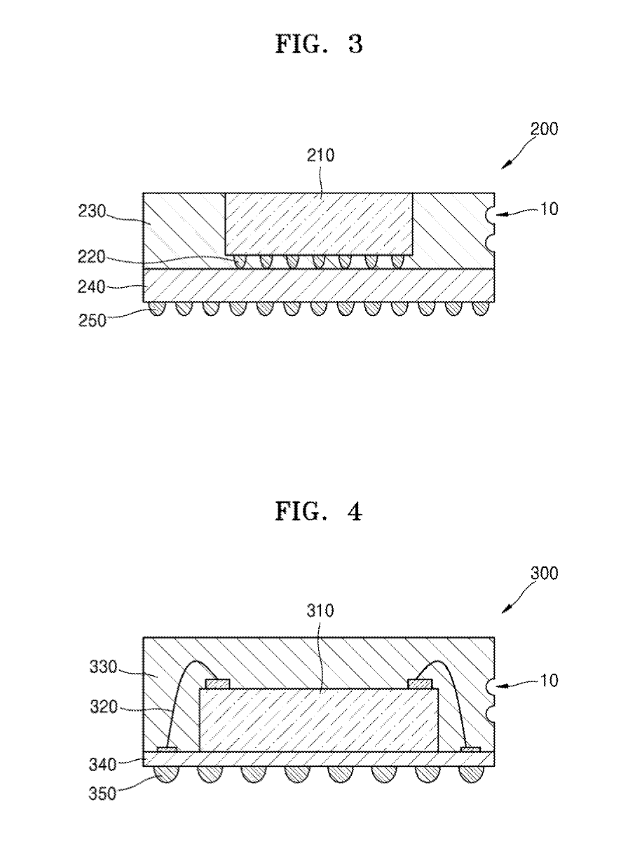

A mold member 130 may cover sides and an upper surface of the semiconductor chip 110. However, as illustrated in FIG. 3, the upper surface of the semiconductor chip 110, shown as semiconductor chip 210, may be exposed through an opening formed in an upper surface of the mold member 130, shown as mold member 230. The mold member 130 may be formed of an epoxy mold compound (EMC). The EMC may have a Young's Modulus of about 15 to 30 GPa, and a coefficient of thermal expansion (CTE) of about 3 to 30 ppm. The mold member 130 is not limited to the EMC, and may be formed of various materials, for example, an epoxy-based material, a thermosetting material, a thermoplastic material, or a UV treatment material. In the case of the thermosetting material, a curing agent of a phenol type, an acid anhydride type, or an amine type and an additive of an acrylic polymer may be included. Furthermore, the mold member 130 may be formed of an epoxy and may include a relatively large amount of a filler. For example, the mold member 130 may be formed of an epoxy-based material having a silica filler of about 80%.

The mold member 130 may be formed by a molded underfill (MUF) process, and thus a material covering an outline of the semiconductor chip 110 may be the same as a material filling a space between the semiconductor chip 110 and the package substrate 140. As illustrated in FIG. 1, the internal connection member 120 may be disposed between the semiconductor chip 110 and the package substrate 140, and the mold member 130 may surround the internal connection member 120.

The upper surface may form an angle of about 90 degrees with at least one side of the mold member 130. In general, an angle of about 90 degrees may be formed between the upper surface and at least one side of the mold member in the process of forming semiconductor packages by cutting a package substrate along a scribe lane. In the semiconductor package 100 having such a structure, a marking pattern 10 having information about the semiconductor chip 100 may be formed in a portion or the entirety of one or more sides of the semiconductor package 100, i.e., in a portion or the entirety of one or more sides of the mold member 130.

In the electronic product market, the demand for portable devices has rapidly increased, and there is an ongoing demand the size and weight of electronic components to be mounted therein. The entire thickness of the semiconductor package 100 has decreased to reduce the size and weight of electronic components, and there is ongoing demand to increase memory capacity. A thin semiconductor chip stack helps realize a large capacity memory in a limited structure of the semiconductor package 100. Thus, the entire thickness of the semiconductor package 100, and thicknesses of the semiconductor chip 110 and the mold member 130 covering the semiconductor chip 110 have continuously decreased.

In general, when a marking pattern having information about the semiconductor chip 100 is formed on the mold member 130 of the semiconductor package 100 by using a laser irradiation method, a heat affected zone can result due to high-temperature heat that is locally generated via the laser irradiation method. The high-temperature heat is transmitted from a surface of the semiconductor package 100 to a certain depth, thus resulting in the inferiority of a semiconductor device within the semiconductor chip 110. Therefore, in the trend of reducing the overall thickness of the semiconductor package 100, and accordingly, the thickness of the mold member 130, a problem may arise in terms of the inferiority of a semiconductor device when forming a marking pattern on an upper surface of the semiconductor package 100 via the laser irradiation method.

Therefore, in an exemplary embodiment, the semiconductor package 100 capable of protecting the semiconductor chip 110 from the heat affected zone may be provided by forming the marking pattern 10 having information about the semiconductor chip 110 on at least one side surface rather than on the upper surface of the semiconductor package 100. When the marking pattern 10 is formed via the laser irradiation method, a recessed portion having a certain depth is formed on the mold member 130, and information in the marking pattern 10 formed in the recessed portion may be read by a recognition device. The marking pattern 10 may be formed on a portion or the entirety of at least one side of the semiconductor package 100.

Furthermore, the marking pattern 10 may be directly formed on at least one side surface of the semiconductor package 100. That is, there is no need to form another material layer and remove a portion thereof or transform a color of another material layer in order to form the marking pattern 10 on the semiconductor package 100.

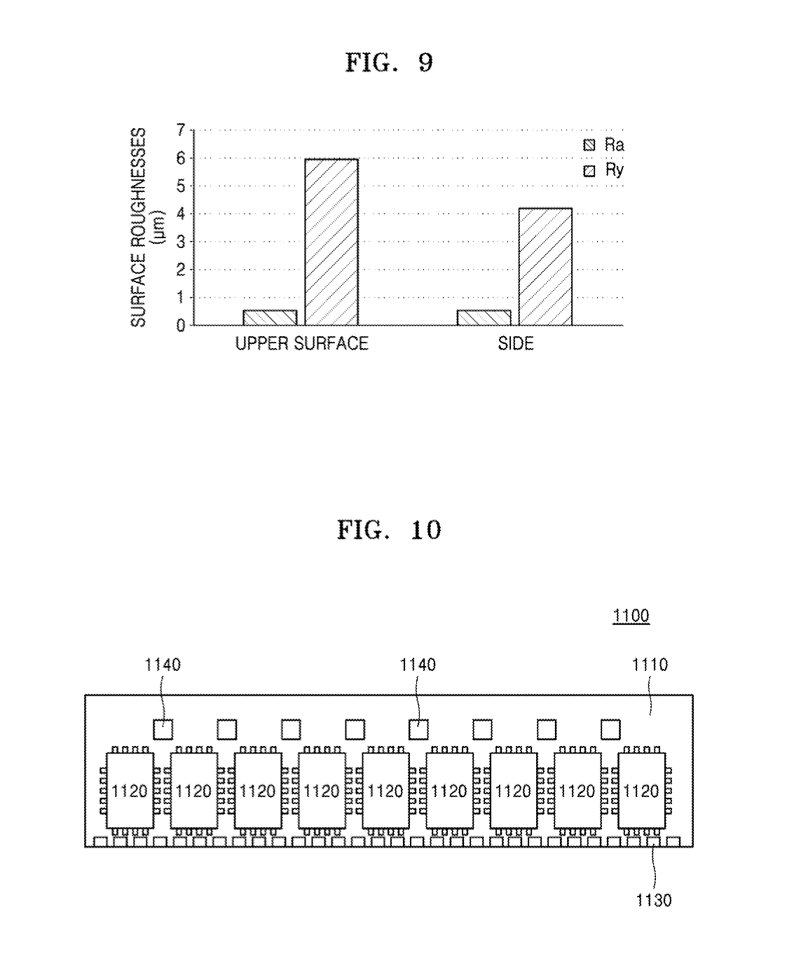

As described above, the forming of the marking pattern 10 on at least one of the side of the semiconductor package 100 may be effectively applied to the semiconductor package 100 in which the upper surface of the mold member 130 forms an angle of about 90 degrees with at least one side of thereof. Furthermore, when the semiconductor package 100 is cut along the scribe lane, a surface roughness of the surface that was cut may be an important factor in ensuring visibility of the marking pattern 10. The surface roughness will be described below in more detail with reference to FIG. 9.

FIG. 2 is a sectional view of a semiconductor package 100 having a marking pattern 20 formed on at least one side thereof by using an inkjet printing method, according to an exemplary embodiment.

Referring to FIG. 2, there are many methods of forming a marking pattern on the semiconductor package 100. A method of forming a marking pattern by laser irradiation is generally used, but the method of forming a marking pattern on the semiconductor package 100 illustrated in FIG. 2 is not limited thereto. The marking pattern 20 having information about a semiconductor chip may be formed on the semiconductor package 100 according to an exemplary embodiment by using an inkjet printing method.

Different from the laser irradiation method that uses heat, the inkjet printing method does not form a heat affected zone on the semiconductor package 100. Thus, a semiconductor device included in a semiconductor chip 110 may be less affected by heat when using the inkjet printing method as compared with using the laser irradiation method. However, in terms of protecting a semiconductor device from defects, since pressure may be applied to the semiconductor package 100 by an inkjet head when the inkjet printing method is performed, it may be still advantageous to form a marking pattern on a side of the semiconductor package 100 rather than on the upper surface.

When the marking pattern 20 is formed on a surface of the mold member 130 via the inkjet printing method, a projecting portion may be formed. In contrast, a recessed portion may be formed when the marking pattern 10 (of FIG. 1) is formed via the laser irradiation method. Therefore, when the marking pattern 20 is formed via the inkjet printing method, the projecting portion with a specific thickness may be formed on the mold member 130, and information in the marking pattern 10 formed in the projecting portion may be read by a recognition device.

FIG. 3 is a sectional view of a semiconductor package 200 of a flip chip structure having a marking pattern 10 on at least one side thereof, according to an exemplary embodiment.

Referring to FIG. 3, a semiconductor package 200 according to an exemplary embodiment is illustrated. The semiconductor package 200 may have a flip chip structure, and an upper surface of a semiconductor chip 210 that is not covered by the mold member 230 may remain exposed. When the upper surface of the semiconductor chip 210 is exposed, heat generated in the semiconductor package 200 may dissipate via the upper surface of the semiconductor chip 210, and a heat sink (not shown) may be selectively attached to the upper surface of the semiconductor chip 210.

As described above, the entire thickness of the semiconductor package 200, along with the thicknesses of the semiconductor chip 210 and the mold member 230 covering the semiconductor chip 210, has continuously decreased. Furthermore, the upper surface of the semiconductor chip 210 included in the semiconductor package 200 may be completely exposed. In the semiconductor package 200 having the structure described above, a marking pattern may be formed not on the exposed part of the semiconductor chip 210 but on an upper surface of the mold member 230 by using a laser irradiation method. In this case, the size of a marking region may not be large enough to display all the marking patterns having information about a semiconductor chip. Therefore, in an exemplary embodiment, the marking pattern 10 may be formed on at least one side of the semiconductor package 200. The marking pattern 10 may be formed on a portion or the entirety of at least one side of the semiconductor package 200.

FIG. 4 is a sectional view of a semiconductor package 300 having a bonding wire structure and having a marking pattern 10 on at least one side thereof, according to an exemplary embodiment.

Referring to FIG. 4, the semiconductor package 300 may have a bonding wire structure, and a mold member 330 may surround a semiconductor chip 310 and bonding wires 320.

The semiconductor package 300 may have a structure other than the flip chip structure described above. For example, the semiconductor package 300 may have a structure in which a bonding pad (not shown) disposed on a semiconductor chip 310 is electrically connected to a package substrate by the bonding wires 320. As the bonding wires 320 have a self-looping characteristic, it may be difficult to have a structure such as that of the semiconductor package 200 of FIG. 3 in which an upper surface of the semiconductor chip 210 is exposed. However, it is also common to reduce the thickness of an upper surface of the mold member 330 in order to reduce the entire thickness of the semiconductor package 300 having the bonding wire structure. Thus, when the marking pattern 10 is formed by using a laser irradiation method, inferiority of a semiconductor device may result due to a localized high-temperature generation in an area of a semiconductor device existing in the semiconductor chip 310.

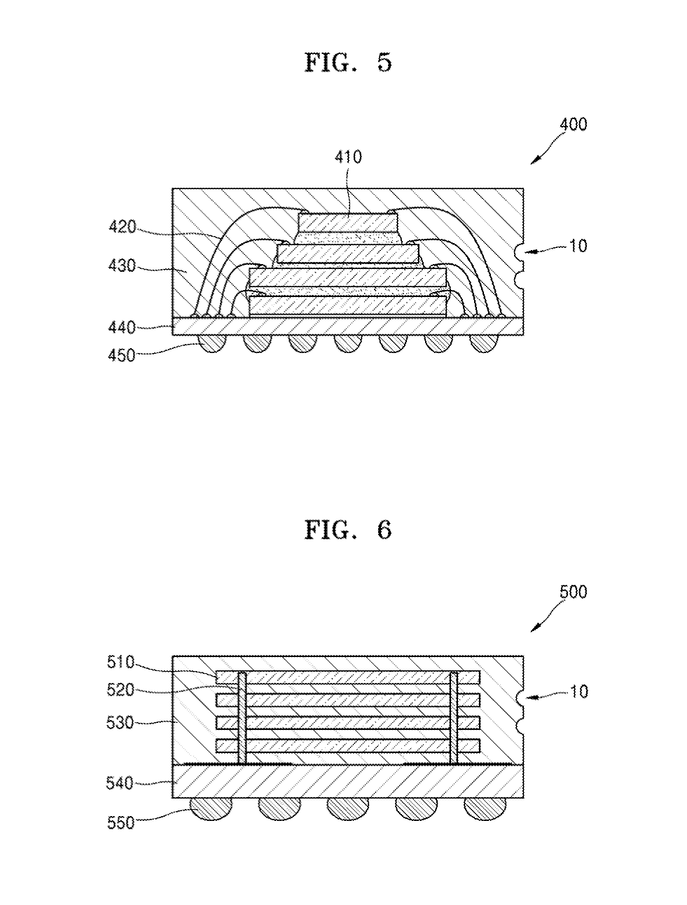

FIG. 5 is a sectional view of a semiconductor package 400 of a semiconductor chip stack structure having a marking pattern 10 on at least one side thereof, according to an exemplary embodiment.

Referring to FIG. 5, the semiconductor package may have a stack structure in which a plurality of semiconductor chips 410 are laminated and stacked The plurality of the semiconductor chips 410 are connected to internal connection members 420, and a mold member 430 surrounds the semiconductor chips 410 and the internal connection members 420.

The internal connection members 420 may be bonding wires but are not limited thereto. For example, the semiconductor chips 410 may have a flip chip structure, and the internal connection members 420 may be solder balls.

The semiconductor package 400 of a laminate structure may include a package substrate 440 and the semiconductor chips 410. The semiconductor chips 410 may include a lower semiconductor chip and an upper semiconductor chip. The lower semiconductor chip may be attached to the package substrate 440, and the upper semiconductor chip may be laminated on the lower semiconductor chip.

The mold member 430 surrounding the semiconductor chips 410 may be formed on the package substrate 440. The mold member 430 may cover the entire upper surface of the package substrate 440, but is not limited thereto. For example, a part of the upper surface of the package substrate 440 may be exposed. The mold member 430 may cover upper surfaces of the semiconductor chips 410, but is not limited thereto. For example, the mold member 430 may surround sides of the semiconductor chips 410 and may expose the upper surfaces of the semiconductor chips 410. When the upper surfaces of the semiconductor chips 410 are exposed, heat generated in the semiconductor package 400 may dissipate via the upper surface of the semiconductor chip 410, and a heat sink (not shown) may be selectively attached to the upper surface of the semiconductor chips 410.

In order to transmit a signal between the semiconductor package 400 of a laminate structure and an external device and/or to supply power to the semiconductor package 400 of a laminate structure, an external connection member 450 may be attached to a lower surface of the package substrate 440.

The marking pattern 10 having information about a semiconductor chip may be formed on at least one side of the semiconductor package 400. That is, the marking pattern 10 may be formed on the mold member. Regarding the semiconductor chips 410 and the heat sink attached to the upper surfaces of the semiconductor chips 410 in the semiconductor package 400 of the laminate structure, upper surfaces of the semiconductor chips 410 or the heat sink may be exposed. Thus, when the marking pattern 10 is formed by using a laser irradiation method, semiconductor device inferiority may result due to high temperature that is directly applied to the semiconductor chip 410 as described above.

FIG. 6 is a sectional view of a semiconductor package 500 having a through silicon via (TSV) structure and having a marking pattern 10 on at least one side thereof, according to an exemplary embodiment.

Referring to FIG. 6, the semiconductor package 500 according to an exemplary embodiment may include a package substrate 540, a semiconductor chips 510, a TSV 520, a mold member 530, and an external connection member 550.

The semiconductor chips 510 may include a body part, a wiring part, a protection part, and the TSV 520. The semiconductor chips 510 may be formed based upon a wafer as described above. The body part, the wiring part, and the protection part are just as described in FIG. 1.

The TSV 520 may be connected to a lower pad by passing through the body part. For reference, a TSV may be divided into a via-first structure, a via-middle structure, and a via-last structure. The via-first represents a structure in which a TSV is formed before an integrated circuit layer is formed. The via-middle represents a structure in which a TSV is formed before a wiring part is formed and after an integrated circuit layer is formed. The via-last represents a structure in which a TSV is formed after a wiring part is formed.

The TSV 520 may include at least one metal. For example, the TSV 520 may include a barrier metal layer (not shown) and a wiring metal layer (not shown). The barrier metal layer may include at least one material chose from among tungsten (W), tungsten nitride (WN), tungsten carbide (WC), titanium (Ti), titanium nitride (TiN), tantalum (Ta), tantalum nitride (TaN), ruthenium (Ru), cobalt (Co), manganese (Mn), nickel (Ni), and nickel-boron (NiB), and may be formed of a monolayer or a multilayer. The wiring metal layer may include copper (Cu) or W. For example, the wiring metal layer may be formed of Cu, copper-tin (CuSn), copper-magnesium (CuMg), copper-nickel (CuNi), copper-zinc (CuZn), copper-palladium (CuPd), copper-gold (CuAu), copper-rhenium (CuRe), copper-tungsten (CuW), W, and W alloy, but is not limited thereto. For example, the wiring metal layer may include at least one from among aluminum (Al), gold (Au), beryllium (Be), bismuth (Bi), Co, Cu, hafnium (Hf), indium (In), Mn, molybdenum (Mo), Ni, lead (Pb), palladium (Pd), platinum (Pt), rhodium (Rh), rhenium (Re), Ru, Ta, tellurium (Te), Ti, W, zinc (Zn), and zirconium (Zr), and may further include at least one laminate structure thereof. However, materials of the TSV 520 are not limited thereto. The barrier metal layer and the wiring metal layer may be formed by a physical vapor deposition (PVD) process or a chemical vapor deposition (CVD) process, but are not limited thereto.

The marking pattern 10 displaying information about a semiconductor chip may be formed on at least one side of the semiconductor package 500 having the TSV 520. Furthermore, the marking pattern may be formed on the mold member 530. As the semiconductor package 500 having the mold member 530 includes a plurality of the semiconductor chips 510, an upper surface of the mold member 530 may be thinner so as to reduce the overall thickness of the semiconductor package 500. Therefore, in the semiconductor package 500 according to the present embodiment, it is advantageous to form the marking pattern 10 on at least one side thereof in terms of reducing the inferiority of a semiconductor device.

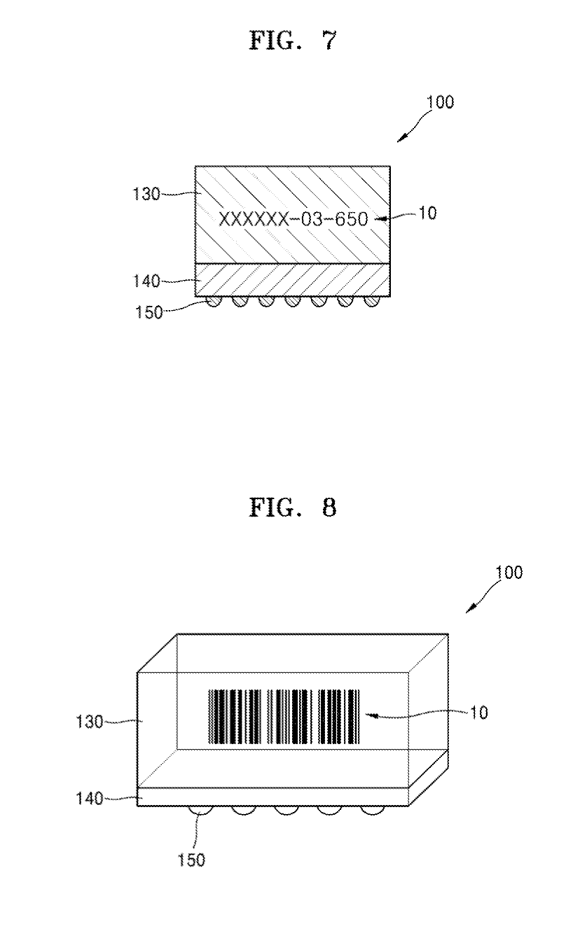

FIG. 7 is a side view of a semiconductor package 100 having a marking pattern 10 on at least one side thereof, according to an exemplary embodiment.

FIG. 8 is a perspective view of a semiconductor package 100 having a marking pattern 10 on at least one side thereof, according to an exemplary embodiment.

Referring to FIGS. 7 and 8, the marking pattern 10 having information about a semiconductor chip is displayed on at least one side of the semiconductor package 100. The marking pattern 10 may include at least one from among a character, a number, an identification symbol, and a bar code. The marking pattern 10 may be formed via various methods such as a laser irradiation method, or an inkjet printing method. The marking pattern 10 may include a variety of information, for example, a manufacturer, a date of manufacture, a serial number, or a type of a semiconductor chip.

Moreover, the marking pattern 10 may be read by a recognition device. Therefore, the marking pattern 10 needs to be visible by the recognition device. Surface roughness of the sides of the semiconductor package 100 will be described in FIG. 9 below in more detail.

FIG. 9 is a graph illustrating surface roughnesses of an upper surface and at least one side of a semiconductor package 100 (of FIG. 1), according to an exemplary embodiment.

Referring to FIGS. 1 and 9, the surface roughnesses of the upper surface and the sides of the semiconductor package 100 are evaluated as an average roughness (Ra) and a maximum height roughness (Ry) of the surface.

In the semiconductor package 100, when the marking pattern 10 is formed on the mold member 130 on the sides of the semiconductor package 100 by cutting the semiconductor package 100 along the scribe lane after forming the mold member 130, there may be a problem with visibility of the marking pattern 10. Thus, in the inventive concept, the surface roughnesses of the upper surface and the sides of the semiconductor package 100 are measured after forming the semiconductor package 100.

Regarding the upper surface of the semiconductor package 100, Ra is about 0.6 to 0.8 μm while Ry is about 6 μm. Regarding the sides of the semiconductor package 100, Ra is about 0.4 to 0.8 μm while Ry is about 4.2 μm.

Since the measured Ra and Ry values of the upper surface and the sides of the semiconductor package 100 are similar, the semiconductor package 100 may be determined as having a structure in which the marking pattern 10 is sufficiently visible.

FIG. 10 is a plan view of a memory module 1100 having semiconductor packages 1120, according to an exemplary embodiment.

Referring to FIG. 10, the memory module 1100 may include a module substrate 1110 and a plurality of semiconductor packages 1120 attached to the module substrate 1110.

The semiconductor package 1120 may include a semiconductor package according to an exemplary embodiment. For example, the semiconductor package 1120 may include the semiconductor package described above with reference to FIGS. 1 to 8.

Connection portions 1130, which are fittable into a main board, may be disposed at one side of the module substrate 1110. Ceramic decoupling capacitors 1140 may be disposed on the module substrate 1110. The memory module 1100 according to an exemplary embodiment is not limited to the configuration of FIG. 14, and may be manufactured in various types.

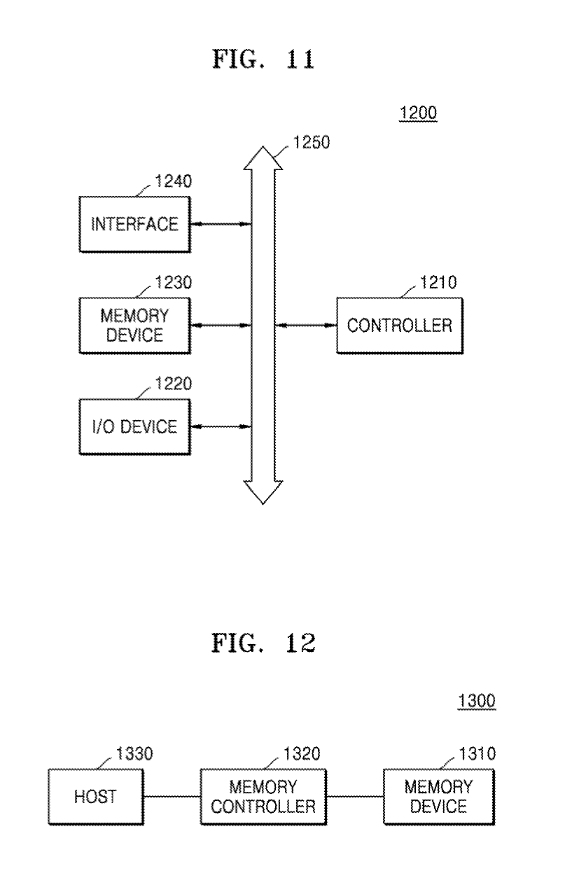

FIG. 11 is a configuration diagram of a system 1200 having a semiconductor package, according to an exemplary embodiment.

Referring to FIG. 11, the system 1200 may include a controller 1210, an input/output device 1220, a memory device 1230, and an interface 1240. The system 1200 may be a mobile system or an information transmitting/receiving system. In some exemplary embodiments, the mobile system may include a personal digital assistant (PDA), a portable computer, a web tablet, a wireless phone, a mobile phone, a digital music player, and a memory card. The controller 1210 may be configured to control an execution program on the system 1200, and may be a microprocessor, a digital processor, a microcontroller, or other similar devices. The input/output device 1220 may be used to input or output data of the system 1200. The system 1200 may be connected to an external device, for example, a personal computer or a network, through the input/output device 1220, and may exchange data with the external device. Examples of the input/output device 1220 may include a keypad, a keyboard, or a display.

The memory device 1230 may store codes and/or data for operations of the controller 1210, or may store data processed by the controller 1210. The memory device 1230 may include a semiconductor package according to an exemplary embodiment. For example, the memory device 1230 may include the semiconductor package described above with reference to FIGS. 1 to 8.

The interface 1240 may be a data transmission path between the system 1200 and an external device. The controller 1210, the input/output device 1220, the memory device 1230, and the interface 1240 may communicate with one another through a bus 1250. The system 1200 may be used in a mobile phone, an MP3 player, a navigation device, a portable multimedia player (PMP), a solid state disk (SSD), or home appliances.

FIG. 12 is a configuration diagram of a memory card 1300 having a semiconductor package, according to an exemplary embodiment.

Referring to FIG. 12, the memory card 1300 may include a memory device 1310 and a memory controller 1320.

The memory device 1310 may store data. In some exemplary embodiments, the memory device 1310 may be a non-volatile memory device that can retain stored data even when power is interrupted. The memory device 1310 may include the semiconductor package according to an exemplary embodiment. For example, the memory device 1310 may include the semiconductor package described above with reference to FIGS. 1 to 8.

The memory controller 1320 may read data from the memory device 1310 in response to a read/write request from a host 1330, or may store data in the memory device 1310.

While the inventive concept has been particularly shown and described with reference to exemplary embodiments thereof, it will be understood that various changes in form and details may be made therein without departing from the spirit and scope of the following claims.

What is claimed is:

1. A semiconductor package comprising:
a semiconductor chip having an upper surface and at least one side surface;
a mold member disposed on the upper surface and the at least one side surface of the semiconductor chip; and
a marking pattern formed on at least one side surface of the mold member,
wherein the marking pattern includes information on the semiconductor chip.

2. The semiconductor package of claim 1, wherein a portion of the upper surface of the semiconductor chip is exposed.

3. The semiconductor package of claim 1, wherein a thickness of the mold member on the upper surface of the semiconductor chip is less than a thickness of the mold member on the at least one side of the semiconductor chip.

4. The semiconductor package of claim 1, wherein the marking pattern is recessed and is readable by a recognition device.

5. The semiconductor package of claim 1, wherein an angle between an upper surface and at least one side of the semiconductor package is a right angle.

6. The semiconductor package of claim 1, wherein the marking pattern comprises a character and an identification symbol indicating information on the semiconductor package.

7. The semiconductor package of claim 6, wherein the marking pattern comprises a bar code shape in which the information on the semiconductor package is stored.

8. The semiconductor package of claim 1, wherein the marking pattern is formed on at least one side surface of the semiconductor package by using a laser irradiation method.

9. The semiconductor package of claim 1, wherein the marking pattern is formed on at least one side surface of the semiconductor package by using an inkjet printing method.

10. A semiconductor package comprising:
a mold member;
a semiconductor chip having a first surface, a second surface facing the first surface and a third surface contacting both the first surface and the second surface, the semiconductor chip having bonding pads disposed on the first surface; and
a marking pattern comprising information on the semiconductor chip and formed on an external surface of the semiconductor package,
wherein the external surface of the semiconductor package is parallel to the third surface.

11. The semiconductor package of claim 10, wherein the mold member covers the third surface, and
the marking pattern is formed on an external surface of the mold member that is parallel to the third surface of the semiconductor chip.

12. The semiconductor package of claim 10, wherein a thickness of the mold member in a direction perpendicular to the first surface is less than a thickness of the mold member in a direction perpendicular to the third surface.

13. The semiconductor package of claim 10, wherein the marking pattern comprises at least one from among a character, a number, an identification symbol, and a bar code.

14. The semiconductor package of claim 10, wherein the marking pattern is directly formed on the external surface of the semiconductor package.

15. A semiconductor package comprising:
a plurality of semiconductor chips, each of the plurality of semiconductor chips having bonding pads;
bonding wires electrically coupled to the bonding pads;
a mold member surrounding the semiconductor chip and the bonding wire; and
a marking pattern comprising information about the semiconductor chip,
wherein the marking pattern is formed on a surface of the mold member.

16. The semiconductor package of claim 15, wherein the marking pattern is formed on a side surface of the mold member.

17. The semiconductor package of claim 15, wherein the marking pattern comprises a character and an identification symbol indicating information about the semiconductor package.

18. The semiconductor package of claim 17, wherein the marking pattern comprises a bar code shape in which the information about the semiconductor package is stored.

19. The semiconductor package of claim 15, wherein the marking pattern is formed on the surface of the mold member by using a laser irradiation method.

20. The semiconductor package of claim 15, wherein the marking pattern is formed on the surface of the mold member by using an inkjet printing method.
